(19) United States
(12) Patent Application Publication
(10) Pub. No.: US 2019/0067636 A1
(43) Pub. Date: Feb. 28, 2019

(54) ORGANIC EL DISPLAY DEVICE

(71) Applicant: Sharp Kabushiki Kaisha, Sakai City, Osaka (JP)

(72) Inventors: Tohru SENOO, Sakai City (JP); Takeshi HIRASE, Sakai City (JP); Takashi OCHI, Sakai City (JP); Tohru SONODA, Sakai City (JP); Mamoru ISHIDA, Sakai City (JP)

(21) Appl. No.: 16/081,043

(22) PCT Filed: Mar. 8, 2017
(86) PCT No.: PCT/JP2017/009284

§ 371 Date: Aug. 30, 2018

(30) Foreign Application Priority Data
Mar. 15, 2016 (JP) 2016-051361

(51) Int. Cl. H01L 51/52; H01L 27/32; H01L 51/00

(52) U.S. Cl. CPC H01L 51/5253; H01L 27/3244; H01L 27/323; H01L 2251/5338; H01L 51/0097; H01L 51/5281; H01L 27/322

(57) ABSTRACT

An organic EL display device includes: a resin substrate; an organic EL element provided on the resin substrate; a foundation layer covering the organic EL element; and a hard coat layer provided on the foundation layer. The difference between the Martens hardness obtained if the hard coat layer is formed on the glass substrate and the Martens hardness obtained if the hard coat layer is formed on the glass substrate via the resin film is less than 34 N/mm².

### TECHNICAL FIELD

The present invention relates to an organic EL display device.

### BACKGROUND ART

Self-luminous organic EL display devices including an organic electroluminescence (EL) element have recently received attention, as display devices alternative to liquid crystal display devices. As an organic EL display device of this type, a repeatedly bendable organic EL display device including a flexible resin substrate, and an organic EL element and various films stacked on the flexible resin substrate has been proposed. Such a repeatedly bendable organic EL display device has been proposed to include a hard coat layer on its outermost surface so that even if a pressure is applied to a display screen by, for example, a pencil, the display screen is less likely to suffer from a permanent plastic deformation (dent).

For example, Patent Document 1 discloses a unit for an image display device, and an image display device using the unit. The unit includes an optical film stack, and a panel for an image display device such as a liquid crystal display panel, an organic EL display panel, or the like. The optical film stack and the panel are stacked via an adhesive layer having a predetermined modulus of elasticity.

### CITATION LIST

### Patent Documents

Patent Document 1: Japanese Unexamined Patent Publication No. 2013-101318

### SUMMARY OF THE INVENTION

### Technical Problem

Suppose that an organic EL display device has an outermost surface (a surface) on which a hard coat layer having a predetermined pencil hardness. Even in such a case, because of the structure of the foundation layer disposed below the hard coat layer, the hard coat layer may not have a pencil hardness originally intended, and thus the hard coat layer may have a permanent plastic deformation (dent). Here, for the organic EL display device having the surface on which the hard coat layer is provided, it is haphazard and inefficient to select a hard coat layer on every occasion depending on the structure of foundation layer.

In view of the foregoing, it is an object of the present invention to easily achieve an organic EL display device having a hard coat layer which is less likely to be plastically deformed.

### Solution to the Problem

To achieve the object, the organic EL display device according to the present invention includes a resin substrate; an organic EL element provided on the resin substrate; a foundation layer covering the organic EL element; and a hard coat layer provided on the foundation layer. A difference between a Martens hardness obtained if the hard coat layer is formed on a glass substrate and a Martens hardness obtained if the hard coat layer is formed on the glass substrate via a resin film is less than 34 N/mm².

### Advantages of the Invention

According to the present invention, the difference between the Martens hardness obtained if the hard coat layer is formed on the glass substrate and the Martens hardness obtained if the hard coat layer is formed on the glass substrate via the resin film is less than 34 N/mm², and thus the organic EL display device having the hard coat layer which is less likely to be plastically deformed can be easily achieved.

### BRIEF DESCRIPTION OF THE DRAWINGS

FIG. 1 is a cross-sectional view showing a schematic configuration of an organic EL display device according to a first embodiment of the present invention.

FIG. 2 is a cross-sectional view showing an internal configuration of the organic EL display device according to the first embodiment of the present invention.

FIG. 3 is a cross-sectional view of an organic EL layer forming part of the organic EL display device according to the first embodiment of the present invention.

FIG. 4 is a first side view describing a method for measuring the Martens hardness of a hard coat layer constituting part of the organic EL display device according to the first embodiment of the present invention.

FIG. 5 is a second side view describing a method for measuring the Martens hardness of the hard coat layer constituting part of the organic EL display device according to the first embodiment of the present invention.

FIG. 6 is a table showing experimental examples of the hard coat layer constituting part of the organic EL display device according to the first embodiment of the present invention.

FIG. 7 is a graph showing relations between the Martens hardness difference ΔHM and the pencil hardness difference obtained in Experimental Examples of the hard coat layer constituting part of the organic EL display device according to the first embodiment of the present invention.

FIG. 8 is a cross-sectional view showing a schematic configuration of an organic EL display device according to a second embodiment of the present invention.

FIG. 9 is a cross-sectional view showing a schematic configuration of an organic EL display device according to a third embodiment of the present invention.

### DESCRIPTION OF EMBODIMENTS

Embodiments of the present invention will now be described in detail with reference to the drawings. Note that the present invention is not limited to the following embodiments.

### First Embodiment

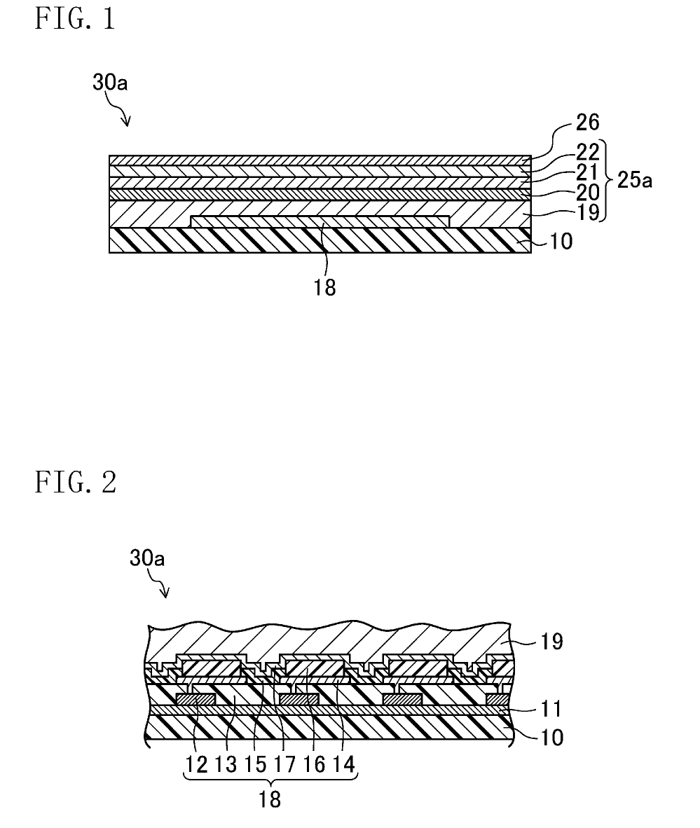

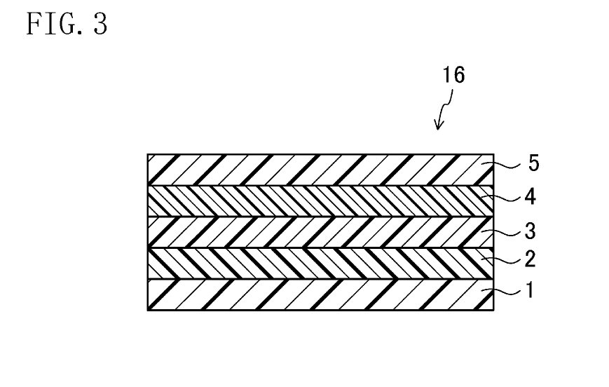

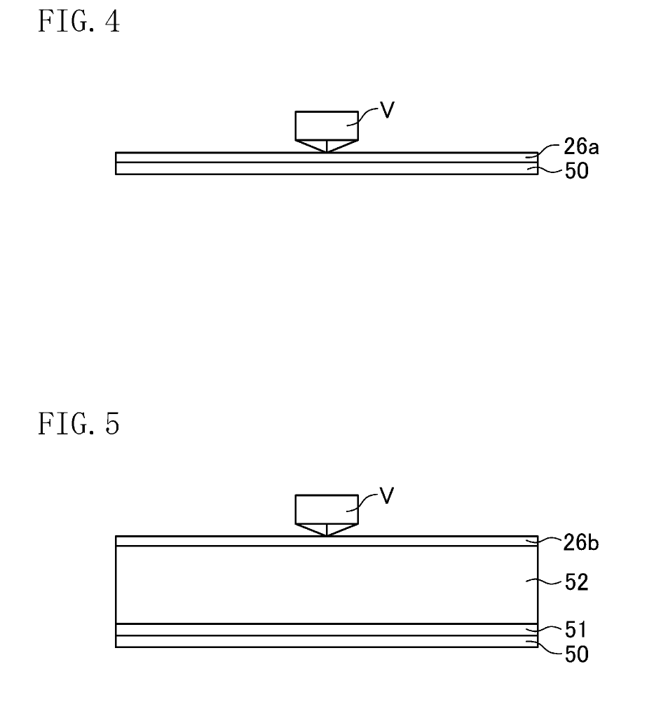

FIGS. 1 to 7 show an organic EL display device according to a first embodiment of the present invention. Here, FIG. 1 is a cross-sectional view showing a schematic configuration of the organic EL display device 30a of this embodiment. FIG. 2 is a cross-sectional view showing an internal configuration for the organic EL display device 30a. FIG. 3 is a cross-sectional view of an organic EL layer 16 forming part of the organic EL display device 30a. FIGS. 4 and 5 are first and second side views respectively illustrating a method for measuring the Martens hardness of hard coat layers 26a and 26b serving as a hard coat layer 26 constituting the organic EL display device 30a.

As shown in FIG. 1, the organic EL display device 30a includes: a base resin substrate 10; an organic EL element 18 provided on the base resin substrate 10 via a base coat film 11 (see FIG. 2); a foundation layer 25a covering the organic EL element 18; and the hard coat layer 26 provided on the foundation layer 25a. Here, in the organic EL display device 30a, a display region to display images is provided in a rectangular shape, and multiple pixels are arranged in a matrix in the display region. For example, each pixel includes a set of sub-pixels arranged adjacent to each other. The set of sub-pixels includes a sub-pixel for gradation display in red, a sub-pixel for gradation display in green, and a sub-pixel for gradation display in blue.

The first resin substrate 10 is a plastic film made of, for example, polyimide resin.

The basecoat film 11 is, for example, an inorganic insulating film such as a silicon dioxide film or a silicon nitride film.

As shown in FIG. 2, the organic EL element 18 includes a plurality of TFTs 12, an interlayer insulating film 13, a plurality of first electrodes 14, an edge cover 15, a plurality of organic EL layers 16, and a second electrode 17 which are sequentially provided over the base coat film 11.

As shown in FIG. 2, each of the TFTs 12 is a switching element provided on the base coat film 11 for an associated one of the sub-pixels. Here, each TFT 12 includes, for example: a gate electrode provided on the base coat film 11; a gate insulating film covering the gate electrode; a semiconductor layer provided over the gate insulating film and overlapping with the gate electrode; and source and drain electrodes provided over the semiconductor layer and facing each other. Note that each TFT 12 configured as a bottom gate TFT in this embodiment may be configured as a top gate TFT.

As shown in FIG. 2, the interlayer insulating film 13 covers each TFT 12, except for a portion of the drain electrode of the TFT 12. Here, the interlayer insulating film 13 is made of, for example, a transparent organic resin material such as acrylic resin.

As shown in FIG. 2, the plurality of first electrodes 14 are arranged in a matrix above the interlayer insulating film 13 such that each first electrode 14 corresponds to an associated one of the sub-pixels. Here, as shown in FIG. 2, the first electrodes 14 are connected to the respective drain electrodes of the TFTs 12 via contact holes formed in the interlayer insulating film 13. The first electrodes 14 have the function of injecting holes (positive holes) into the organic EL layers 16. To increase the efficiency in injecting positive holes into the organic EL layers 16, the first electrodes 14 are preferably made of a material having a high work function. Non-limiting examples of materials for the first electrodes 14 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The first electrodes 14 may also be made of an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). Furthermore, the material for the first electrodes 14 may also be a conductive oxide such as tin oxide (SnO), zinc oxide (ZnO), indium tin oxide (ITO), and indium zinc oxide (IZO), for example. Moreover, the first electrodes 14 may be multilayers containing the above materials. Examples of the materials having a high work function include indium tin oxide (ITO) and indium zinc oxide (IZO).

The edge cover 15 is formed in a grid pattern to cover a peripheral portion of each first electrode 14 as shown in FIG. 2. Examples of materials for the edge cover 15 include an inorganic film of silicon dioxide (SiO₂), silicon nitride (SiNx, where x is a positive number) such as Si₃N₄ and silicon oxynitride (SiNO), or an organic film of polyimide resin, acrylic resin, polysiloxane resin, and novolak resin.

As shown in FIG. 2, the plurality of organic EL layers 16 are each provided on a respective one of the first electrodes 14, and are arranged in a matrix so as to correspond to the sub-pixels. Here, as shown in FIG. 3, each organic EL layer 16 includes a positive hole injection layer 1, a positive hole transport layer 2, a light-emitting layer 3, an electron transport layer 4, and an electron injection layer 5, which are provided over the associated first electrode 14 in this order.

The positive hole injection layer 1 is also called an anode buffer layer, and has the function of bringing the energy levels of the first electrodes 14 and the organic EL layers 16 closer to each other and increasing efficiency in injection of positive holes from the first electrodes 14 into the organic EL layers 16. Here, non-limiting examples of materials for the positive hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The positive hole transport layer 2 has the function of increasing an efficiency in transportation of positive holes from the first electrodes 14 to the organic EL layers 16. Here, non-limiting examples of materials for the positive hole transport layer 2 include porphyrin derivatives, aromatic tertiary amine compounds, styryl amine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

When a voltage is applied from the first electrodes 14 and the second electrode 17, positive holes and electrons are respectively injected from the first electrodes 14 and the second electrode 17 into the light-emitting layer 3, in which the positive holes and the electrons are recombined with each other. The light-emitting layer 3 is made of a material having high luminous efficiency. Non-limiting examples of materials for the light-emitting layer 3 include metal oxinoid compounds (8-hydroxyquinoline metal complexes), naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bis(styryl)benzene derivatives, tris(styryl)benzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron transport layer 4 functions to efficiently move electrons to the light-emitting layer 3. Here, non-limiting examples of materials for the electron transport layer 4 includes, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 has the function of bringing the energy levels of the second electrode 17 and the organic EL layers 16 closer to each other and increasing efficiency in injection of electron from the second electrode 17 into the organic EL layers 16. This function contributes to reduction in the drive voltage of the organic EL element 18. The electron injection layer 5 may also be called a cathode buffer layer. Here, non-limiting examples of materials for the electron injection layer 5 include inorganic alkaline compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As shown in FIG. 2, the second electrode 17 covers the organic EL layers 16 and the edge cover 15. The second electrode 17 has the function of injecting electrons into the organic EL layers 16. To increase efficiency in injecting electrons into the organic EL layers 16, the second electrode 17 is preferably made of a material having a low work function. Here, non-limiting examples of materials for the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 17 may also be made of, for example, an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 17 may also contain, for example, a conductive oxide such as tin oxide (SnO), zinc oxide (ZnO), indium tin oxide (ITO), and indium zinc oxide (IZO). Moreover, the second electrode 17 may be multilayers containing the above materials. Non-limiting examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As shown in FIG. 1, the foundation layer 25a includes a sealing film 19 covering the organic EL element 18, a counter resin substrate 20 provided on the sealing film 19, a polarizing plate 21 provided on the counter resin substrate 20, and a touch panel 22 provided on the polarizing plate 21.

The sealing film 19 has the function of protecting the organic EL element 18 against moisture and oxygen. Here, examples of materials for the sealing film 19 include inorganic materials such as silicon dioxide (SiO₂), aluminum oxide (Al₂O₃), silicon nitride (SiNx, where x is a positive number) such as Si₃N₄, and silicon carbonitride (SiCN); and organic materials such as acrylate, polyurea, parylene, polyimide, and polyamide. Note that the sealing film 19 is, for example, a single layer film or a laminated film of an inorganic film made of the inorganic material, or a laminated film including an inorganic film made of the inorganic material and an organic film made of the organic material.

The counter resin substrate 20 is a plastic film made of, for example, polyimide resin.

The polarizing plate 21 includes a polarizer layer obtained by uniaxially stretching a polyvinyl alcohol film that has adsorbed iodine, and a pair of protective films made of triacetylcellulose and sandwiching the polarizer layer.

The touch panel 22 includes, for example, a plastic film made of polyimide, polyethylene terephthalate, or the like, and a capacitive touch panel layer provided on the plastic film and including a transparent electrode or the like.

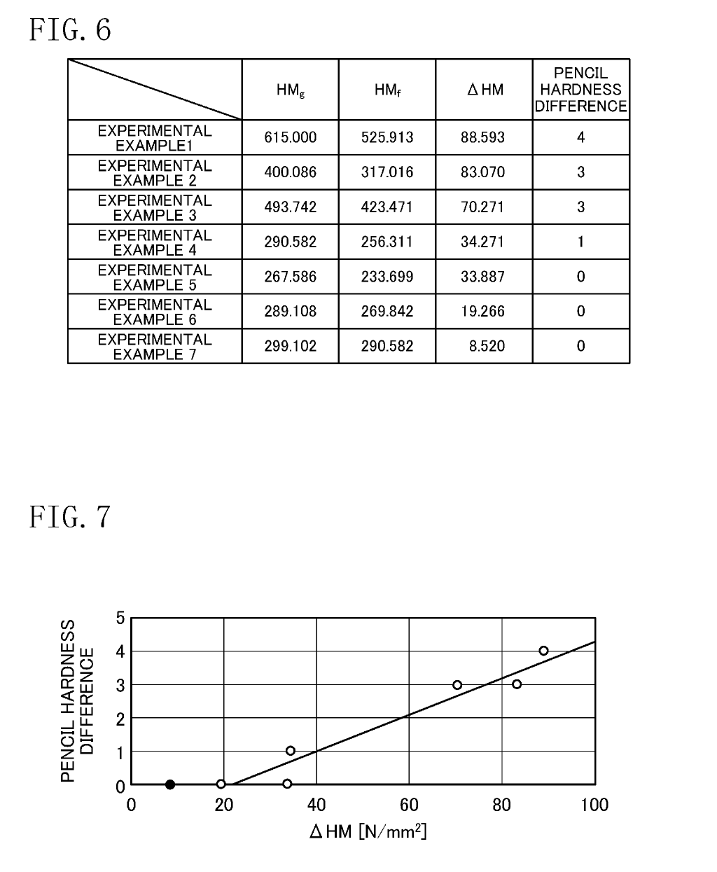

The hard coat layer 26 is made of, for example, silicone resin, acryl urethane resin, or the like having a thickness of about 5 μm to 20 μm. A difference ΔHM (see the table in FIG. 6) between the Martens hardness HM_{g} (see the same table in FIG. 6) obtained if the hard coat layer 26 (the hard coat layer 26a) is formed on a glass substrate 50 as shown in FIG. 4 and the Martens hardness HM_{f} (see the same table in FIG. 6) obtained if the hard coat layer 26 (the hard coat layer 26b) is formed on the glass substrate 50 via an adhesive layer 51 and a resin film 52 as shown in FIG. 5 is 0 N/mm² or more and less than 34 N/mm². The Martens hardnesses HM_{g} and HM_{f} of the hard coat layers 26a and 26b are determined by F/(26.43h²), where h is a maximum indentation depth (mm) to which a Vickers indenter V (see FIGS. 4 and 5) can be pressed against each component by nanoindentation (ISO 14577) under a load F of 4 mN to 6 mN (F=4.4 mN in each of Experimental Examples described below). The glass substrate 50 is, for example, non-alkali glass or the like having a thickness of about 0.7 mm to 1 mm. The adhesive layer 51 is made of, for example, a cyanoacrylate resin or the like having a thickness of about 20 μm to 50 μm. The resin film 52 is made of, for example, a polyethylene terephthalate resin, a polyimide resin or the like having a thickness of about 25 μm to 200 μm. Note that, in this embodiment, the method of measuring the Martens hardness HM_{g} and HM_{f} by pressing the Vickers indenter V against the surfaces of the hard coat layers 26a and 26b has been exemplified. Alternatively, the Vickers indenter V may be pressed against side surfaces of the hard coat layers 26a and 26b to measure the Martens hardness HM_{g} and HM_{f}.

The organic EL display device 30a having the configuration described above is flexible, and capable of displaying an image by causing the light-emitting layer 3 of the organic EL layer 16 to appropriately emit light in each sub-pixel via the TFT 12.

The organic EL display device 30a can be produced by, for example, forming the base coat film 11, the organic EL element 18, and the sealing film 19 on the surface of the base resin substrate 10 by a well-known method to manufacture the organic EL display panel, then attaching the counter resin substrate 20, the polarizing plate 21, and the touch panel 22 to the surface of the organic EL display panel, and then forming the hard coat layer 26 on the surface of the touch panel 22.

Next, the specific experiments conducted to select the hard coat layer 26 will be described. Here, FIG. 6 is a table showing Experimental Examples conducted to select the hard coat layer 26. FIG. 7 is a graph showing relations between the Martens hardness difference ΔHM and the pencil hardness difference obtained in Experimental Examples of the hard coat layer 26 in the table of FIG. 6. Note that, in FIG. 7, the graph contains white dots indicating the results of Experimental Examples 1 to 6, and a black dot indicating the result of Experimental Example 7.

Specifically, the hard coat materials of Experimental Examples 1 to 6 described below were used to form the hard coat layer 26a having a thickness of 10 μm on the glass substrate 50 made of non-alkali glass having a thickness of 0.7 mm, and then the Martens hardness HM_{g} and the pencil hardness (JIS-K 5600-5-4) of the hard coat layer 26a were measured. Similarly, the hard coat materials of Experimental Examples 1 to 6 described below were used to form the adhesive layer 51 and the resin film 52 on the glass substrate 50. Then, the hard coat layer 26b having a thickness of 10 μm was formed on the resin film 52, and the Martens hardness HM_{f} and the pencil hardness of the hard coat layer 26b were measured. Here, the adhesive layer 51 is a coating-type adhesive having a thickness of 50 μm. The resin film 52 is a polyimide film having a thickness of 100 μm. Then, in each of Experimental Examples 1 to 6, the difference ΔHM between the Martens hardness HM_{g} of the hard coat layer 26a and the Martens hardness HM_{f} of the hard coat layer 26b was determined, and the difference between the pencil hardness of the hard coat layer 26a and the pencil hardness of the hard coat layer 26b, i.e., the pencil hardness difference was determined.

Experimental Example 1: Organic-inorganic hybrid resin of “TR-3013” manufactured by ATOMIX CO., LTD.

Experimental Example 2: Organic-inorganic hybrid resin of “IM-357H” manufactured by ATOMIX CO., LTD.

Experimental Example 3: Organic-inorganic hybrid resin of “AN-L82” manufactured by ATOMIX CO., LTD.

Experimental Example 4: Organic-inorganic hybrid resin of “STR-SiA” manufactured by Taisei Fine Chemical Co., Ltd.

Experimental Example 5: Organic-inorganic hybrid resin of “IM-557H” manufactured by ATOMIX CO., LTD.

Experimental Example 6: Organic-inorganic hybrid resin of “ARONIX (registered trademark)” manufactured by Toagosei Co., Ltd.

As shown in the graph of FIG. 7, it has been found as the results of Experimental Examples 1 to 6 that there is a positive correlation between the ΔHM and the pencil hardness difference, and the pencil hardness difference is 0 if ΔHM is less than 34 N/mm² (which is an intermediate value between Experimental Examples 4 and 5). Accordingly, if the hard coat layer in which ΔHM is less than 34 N/mm² is selected, the pencil hardness difference becomes 0, and the plastic deformation of the hard coat layer can be reduced.

Here, in Experimental Examples 1 to 6, the value of ΔHM in which the pencil hardness difference was 0 was studied regarding the hard coat layer on the resin film of a single layer film, but the same can be applied to laminated films such as an organic EL display device.

Specifically, as Experimental Example 7, the hard coat material of Experimental Example 6 was used to form the adhesive layer 51 on the glass substrate 50. Then, the hard coat layer having a thickness of 10 μm was formed on the adhesive layer 51, and the Martens hardness HM_{g} and the pencil hardness of the hard coat layer were measured. Further, the hard coat material of Experimental Example 6 was used to produce the organic EL display device 30a on the glass substrate 50. Then, the Martens hardness HM_{f} and the pencil hardness of the hard coat layer 26 (10 μm thickness) formed on the surface of the organic EL display device 30a were measured. Then, similarly to Experimental Examples 1 to 6, the Martens hardness difference ΔHM and the pencil hardness difference were determined. As a result, as shown in the table of FIG. 6 and the graph of FIG. 7, the Martens hardness difference ΔHM was 8.520 N/mm² which was 0 N/mm or more and less than 34 N/mm², and the pencil hardness difference was 0.

As can be seen, the organic EL display device 30a of this embodiment can provide the following advantages.

The difference ΔHM between the Martens hardness HM_{g} obtained if the hard coat layer 26 (the hard coat layer 26a) is formed on the glass substrate 50 and the Martens hardness HM_{f} obtained if the hard coat layer 26 (the hard coat layer 26b) is formed on the glass substrate 50 via the adhesive layer 51 and the resin film 52 is 0 N/mm or more and less than 34 N/mm², and thus the pencil hardness differences of the hard coat layers 26a and 26b are 0. Thus, the pencil hardness of the hard coat layer 26a on the glass substrate 50 and the pencil hardness of the hard coat layer 26b on the resin film 52 can be substantially the same. As a result, the hard coat layer 26 having a desired pencil hardness (e.g., 6H) is provided on the surface of the device without being affected by the structure of the foundation layer 25a. Thus, the organic EL display device 30a which is less likely to be plastically deformed can be easily achieved.

### Second Embodiment

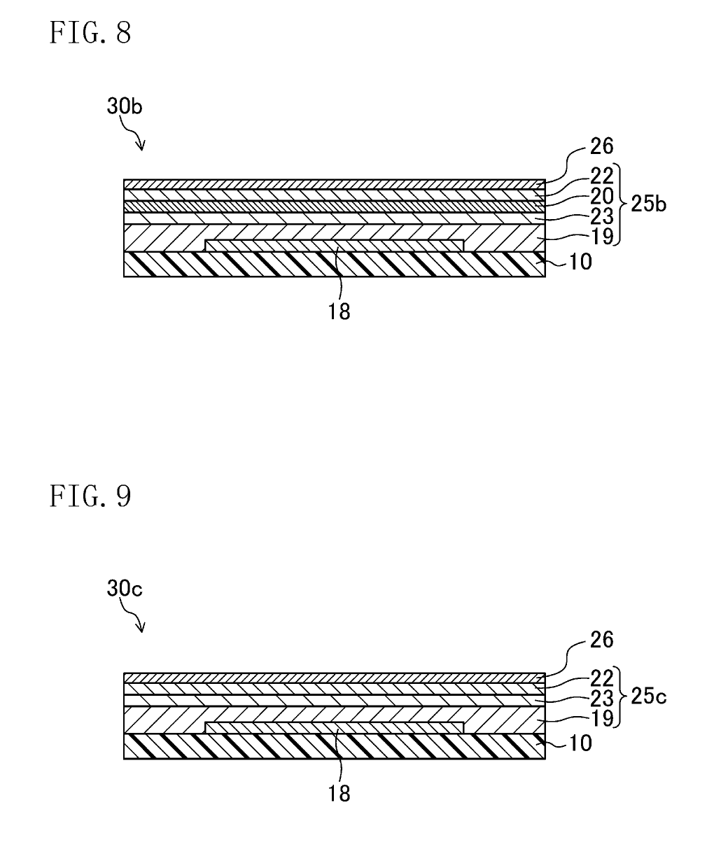

FIG. 8 shows an organic EL display device according to a second embodiment of the present invention. Here, FIG. 8 is a cross-sectional view showing a schematic configuration of an organic EL display device 30b of this embodiment. In the embodiments below, components equivalent to those shown in FIGS. 1 to 7 are denoted by the same reference characters, and the detailed explanation thereof will be omitted.

In the first embodiment, the organic EL display device 30a including the polarizing plate 21 has been exemplified. On the other hand, in this embodiment, an organic EL display device 30b including a color filter 23 instead of the polarizing plate 21 is exemplified.

As shown in FIG. 8, the organic EL display device 30b includes: a base resin substrate 10; an organic EL element 18 provided on the base resin substrate 10 via a base coat film 11 (see FIG. 2); a foundation layer 25b covering the organic EL element 18; and the hard coat layer 26 provided on the foundation layer 25b. Note that the structure of each of pixels arranged in a display region of the organic EL display device 30b is substantially the same as that of each of the pixels arranged in a display region of the organic EL display device 30a of the first embodiment.

As shown in FIG. 8, the foundation layer 25b includes a sealing film 19 covering the organic EL element 18, a color filter 23 provided on the sealing film 19, a counter resin substrate 20 provided on the color filter 23, and a touch panel 22 provided on the counter resin substrate 20.

The color filter layer 23 includes, for example, a black matrix provided in a grid pattern to shield light among the plurality of sub-pixels; and a plurality of coloring layers each provided the respective grids of the black matrix and including a red layer, a green layer, or a blue layer arranged in a matrix pattern.

The organic EL display device 30b having the configuration described above is flexible, and capable of displaying an image by causing the light-emitting layer 3 of the organic EL layer 16 to EL appropriately emit light in each sub-pixel via the TFT 12.

Similarly to the first embodiment, the organic EL display device 30b can be produced by, for example, producing the organic EL display panel, then attaching the counter resin substrate 20 having a back face on which the color filter 23 is formed in advance and the touch panel 22 to the surface of the organic EL display panel, and then forming the hard coat layer 26 on the surface of the touch panel 22.

As can be seen, the organic EL display device 30b of this embodiment can provide the following advantages.

Similarly to the first embodiment, the difference ΔHM between the Martens hardness HM_{g} obtained if the hard coat layer 26 (the hard coat layer 26a) is formed on the glass substrate 50 and the Martens hardness HM_{f} obtained if the hard coat layer 26 (the hard coat layer 26b) is formed on the glass substrate 50 via the adhesive layer 51 and the resin film 52 is 0 N/mm or more and less than 34 N/mm², and thus the pencil hardness differences of the hard coat layers 26a and 26b are 0. Thus, the pencil hardness of the hard coat layer 26a on the glass substrate 50 and the pencil hardness of the hard coat layer 26b on the resin film 52 can be substantially the same. As a result, the hard coat layer 26 having a desired pencil hardness (e.g., 6H) is provided on the surface of the device without being affected by the structure of the foundation layer 25b. Thus, the organic EL display device 30b which is less likely to be plastically deformed can be easily achieved.

### Third Embodiment

FIG. 9 shows an organic EL display device according to a third embodiment of the present invention. Here, FIG. 9 is a cross-sectional view showing a schematic configuration of an organic EL display device 30c of this embodiment.

In the first and second embodiments, the organic EL display devices 30a and 30b each including the counter resin substrate 20 have been exemplified. On the other hand, in this embodiment, the organic EL display device 30c that does not include a counter resin substrate is exemplified.

As shown in FIG. 9, the organic EL display device 30c includes: a base resin substrate 10; an organic EL element 18 provided on the base resin substrate 10 via a base coat film 11 (see FIG. 2); a foundation layer 25c covering the organic EL element 18; and the hard coat layer 26 provided on the foundation layer 25c. Note that the structure of each of pixels arranged in a display region of the organic EL display device 30c is substantially the same as that of each of the pixels arranged in a display region of the organic EL display device 30a of the first embodiment.

As shown in FIG. 9, the foundation layer 25c includes a sealing film 19 covering the organic EL element 18, a color filter 23 provided on the sealing film 19, and a touch panel 22 provided on the color filter 23.

The organic EL display device 30a having the configuration described above is flexible, and capable of displaying an image by causing the light-emitting layer 3 of the organic EL layer 16 to appropriately emit light in each sub-pixel via the TFT 12.

Similarly to the first embodiment, the organic EL display device 30c can be produced by, for example, producing the organic EL display panel, then attaching the touch panel 22 having a back face on which the color filter 23 is formed in advance to the surface of the organic EL display panel, and then forming the hard coat layer 26 on the surface of the touch panel 22.

As can be seen, the organic EL display device 30c of this embodiment can provide the following advantages.

Similarly to the first and second embodiments, the difference ΔHM between the Martens hardness HM_{g} obtained if the hard coat layer 26 (the hard coat layer 26a) is formed on the glass substrate 50 and the Martens hardness HM_{f} obtained if the hard coat layer 26 (the hard coat layer 26b) is formed on the glass substrate 50 via the adhesive layer 51 and the resin film 52 is 0 N/mm or more and less than 34 N/mm², and thus the pencil hardness differences of the hard coat layers 26a and 26b are 0. Thus, the pencil hardness of the hard coat layer 26a on the glass substrate 50 and the pencil hardness of the hard coat layer 26b on the resin film 52 can be substantially the same. As a result, the hard coat layer 26 having a desired pencil hardness (e.g., 6H) is provided on the surface of the device without being affected by the structure of the foundation layer 25c. Thus, the organic EL display device 30c which is less likely to be plastically deformed can be easily achieved.

In the organic EL display device 30c, the touch panel 22 serves also as the counter resin substrate layer 20 of the first and second embodiments. This can reduce the thickness of the organic EL display device 30c, the costs of components, and manufacturing cost.

### Other Embodiments

In the above embodiments, the organic EL display device which has the surface on which the hard coat layer is provided, and which can be bent repeatedly is exemplified. Alternatively, the present invention applicable to other display devices such as a liquid crystal display device.

Moreover, in each of the above embodiments, the organic EL layer has been exemplified as a layer having a stacked structure of the five layers, namely, the positive hole injection layer, a positive hole transport layer, the light-emitting layer, the electron transport layer, and the electron injection layer. Alternatively, the organic EL layer may have a stacked structure of three layers including a positive hole injection and transport layer, a light-emitting layer, and an electron transport and injection layer, for example.

In each of the above embodiments, the organic EL display device in which the first electrode functions as the anode and the second electrode functions as the cathode has been exemplified. Alternatively, the present invention is applicable to an organic EL display device in which the stacked structure of the organic EL element is inverted, the first electrode functions as the cathode, and the second electrode functions as the anode.

In each of the above embodiments, the organic EL display device including the TFT having, as the drain electrode, an electrode connected to the first electrode has been exemplified. Alternatively, the present invention is applicable to an organic EL display device including the TFT having an electrode connected to the first electrode and called a source electrode.

### INDUSTRIAL APPLICABILITY

As can be seen from the foregoing description, the present invention is useful for a flexible organic EL display device.

### DESCRIPTION OF REFERENCE CHARACTERS

V Vickers Indenter
10 Base Resin Substrate
18 Organic EL Element
22 Touch panel
23 Color Filter
25a to 25c Foundation Layer
26, 26a, 26b Hard Coat Layer
30a to 30c Organic EL Display Device
50 Glass Substrate
52 Resin Film

1. An organic EL display device, comprising:
a resin substrate;
an organic EL element provided on the resin substrate;
a foundation layer covering the organic EL element; and
a hard coat layer provided on the foundation layer,
wherein
a difference between
a Martens hardness obtained if the hard coat layer is formed on a glass substrate and
a Martens hardness obtained if the hard coat layer is formed on the glass substrate via a resin film
is less than 34 N/mm².

2. An organic EL display device, comprising:
a resin substrate;
an organic EL element provided on the resin substrate;
a foundation layer covering the organic EL element; and
a hard coat layer provided on the foundation layer,
wherein
a difference between
a Martens hardness obtained if the hard coat layer is formed on a glass substrate and
a Martens hardness obtained if the hard coat layer is formed on the glass substrate via an organic EL element
is less than 34 N/mm².

3. The organic EL display device of claim 1, wherein
a pencil hardness obtained if the hard coat layer is formed on the glass substrate is equal to a pencil hardness obtained if the hard coat layer is formed on the glass substrate via the resin film.

4. The organic EL display device of claim 2, wherein
a pencil hardness obtained if the hard coat layer is formed on the glass substrate is equal to a pencil hardness obtained if the hard coat layer is formed on the glass substrate via the organic EL element.

5. The organic EL display device of claim 1, wherein
the Martens hardness of the hard coat layer is determined by F/(26.43 h²), where h is a maximum indentation depth (mm) to which a Vickers indenter can be pressed by nanoindentation under a load F of 4 mN to 6 mN.

6. The organic EL display device of claim 1, wherein
the foundation layer includes a touch panel.

7. The organic EL display device of claim 1, wherein
the foundation layer includes a color filter.

8. The organic EL display device of claim 1, wherein
the hard coat layer is provided on a surface of the device.
